(19) United States
(12) Patent Application Publication
(10) Pub. No.: US 2020/0325574 A1
(43) Pub. Date: Oct. 15, 2020

(54) SINGLE-STEP DIRECT GROWTH OF LARGE-AREA GRAPHENE AND GRAPHENE-BASED NANOSTRUCTURES ON SILICON BY PLASMA-ENHANCED CHEMICAL VAPOR DEPOSITION

(71) Applicant: California Institute of Technology, Pasadena, CA (US)

(72) Inventors: Wei-Shiuan Tseng, Pasadena, CA (US); Nai-Chang Yeh, Pasadena, CA (US)

(21) Appl. No.: 16/847,537

(22) Filed: Apr. 13, 2020

Related U.S. Application Data
(60) Provisional application No. 62/832,749, filed on Apr. 11, 2019.
(60) Provisional application No. 62/936,976, filed on Nov. 18, 2019.
(60) Provisional application No. 62/985,788, filed on Mar. 5, 2020.

(51) Int. Cl. C23C 16/26; C23C 16/511; H01L 21/02

(52) U.S. Cl. CPC C23C 16/26; C23C 16/511; H01L 21/0262; H01L 21/02527; H01L 21/02381

(57) ABSTRACT

A method of growing a plurality of graphene sheets includes providing a substrate comprising silicon, placing the substrate in a growth chamber, and flowing a gaseous carbon containing precursor and a carrier gas into the growth chamber. A partial pressure ratio of the gaseous carbon containing precursor to the carrier gas is less than 5.5. The method also includes generating a CMOS compatible microwave plasma in the growth chamber. The CMOS compatible microwave plasma is characterized by a power density between 60 W/cm³ and 80 W/cm³. The method further includes subjecting the substrate to the microwave plasma and growing the plurality of graphene sheets to fully cover the substrate.

### CROSS-REFERENCES TO RELATED APPLICATIONS

This application claims priority to U.S. Provisional Patent Application No. 62/832,749, filed on Apr. 11, 2019, U.S. Provisional Patent Application No. 62/936,976, filed on Nov. 18, 2019, and U.S. Provisional Patent Application No. 62/985,788, filed on Mar. 5, 2020, the disclosures of which are hereby incorporated by reference in their entirety for all purposes.

### BACKGROUND OF THE INVENTION

Chemical vapor deposition (CVD) of graphene on metallic substrates (e.g., Cu, Ni) at high temperatures (˜1000° C.) has been the most common process for large-scale synthesis of graphene. However, high-temperature growth processes are incompatible with Si-CMOS technology. Moreover, the synthesis of graphene on metallic substrates requires additional sample transfer processes to semiconducting substrates, which often result in degradation of the sample quality. Thus, there is a need in the art for methods and systems for the direct growth of graphene on silicon for better integration of graphene into current semiconductor industry processes.

### SUMMARY OF THE INVENTION

Embodiments of the present invention relate to a general process that can be used to deposit graphene directly on substrates (e.g., silicon, silicon dioxide, or diamond-like carbon) with full surface coverage utilizing a single step plasma-enhanced CVD (PECVD) process. As described herein, embodiments of the present invention provide a single-step method for large-area, for example, on the order of square centimeters, direct growth of horizontal graphene sheets and vertical graphene nano-walls by PECVD on silicon substrates without active heating.

According to an embodiment of the present invention, a method of growing a plurality of graphene sheets on a silicon substrate using plasma-enhanced chemical vapor deposition (PECVD) is provided. The method includes placing the silicon substrate in a growth chamber. The silicon substrate has a growth area of greater than or equal to 1 cm² and less than or equal to 1590 cm². The method also includes forming a reduced pressure in the growth chamber and then flowing methane gas and hydrogen gas into the growth chamber to establish a growth chamber pressure. In some embodiments, the method includes establishing a growth chamber pressure of about 500 mTorr. A ratio of methane gas partial pressure to hydrogen gas partial pressure is greater than 3.2 and less than 5.5. The method further includes applying, to the growth chamber, a microwave signal having a power between 60 and 80 Watts in a volume of about 1 cm³ to generate a microwave plasma in the growth chamber. During generation of the microwave plasma, the silicon substrate is characterized by a growth temperature less than 520° C. Additionally, the method includes forming, in a processing time less than or equal to ten minutes, the plurality of graphene sheets on the silicon substrate. The plurality of graphene sheets are characterized by a frictional coefficient ranging between 0.0055 and 0.26. Furthermore, the method includes fully covering the silicon substrate with the plurality of graphene sheets.

According to another embodiment of the present invention, a method of growing a plurality of graphene sheets is provided. The method includes providing a substrate comprising silicon, placing the substrate in a growth chamber, and flowing a gaseous carbon containing precursor and a carrier gas into the growth chamber. A partial pressure ratio of the gaseous carbon containing precursor to the carrier gas is less than 5.5. The method also includes generating a CMOS compatible microwave plasma in the growth chamber. The CMOS compatible microwave plasma is characterized by a power density between 60 W/cm³ and 80 W/cm³. The method further includes subjecting the substrate to the microwave plasma and growing the plurality of graphene sheets to fully cover the substrate.

In an embodiment, the substrate comprises a silicon oxide layer, for example, silicon dioxide, coupled to a silicon substrate. The method can also include forming a reduced pressure in the growth chamber prior to flowing the gaseous carbon containing precursor and the carrier gas into the growth chamber. Additionally, growing the plurality of graphene sheets can be performed in a processing time less than or equal to ten minutes. In a particular embodiment, the plurality of graphene sheets on the silicon substrate are characterized by an oxygen concentration less than 5% and a silicon concentration less than 1%. In another particular embodiment, an XPS spectrum for the plurality of graphene sheets on the silicon substrate includes a carbon peak and an oxygen peak and is free of silicon peaks.

Numerous benefits are achieved by way of the present disclosure over conventional techniques. For example, embodiments of the present disclosure can provide methods and systems for single-step direct PECVD growth of graphene on large-area silicon substrates with full coverage. These novel graphene multilayer structures open up a new pathway towards novel optoelectronic applications that are based on intimate integration of graphene and silicon, such as atomically thin transistors and biosensors. These and other embodiments of the disclosure, along with many of its advantages and features, are described in more detail in conjunction with the text below and corresponding figures.

### BRIEF DESCRIPTION OF THE DRAWINGS

FIGS. 1A-1F are schematic diagrams illustrating the graphene growth process according to an embodiment of the present invention.

FIG. 1G is a plot illustrating gas flow rates prior to, during, and after a graphene growth process according to an embodiment of the present invention.

FIG. 2A is an SEM image of a multilayer graphene structure fully covering a silicon substrate according to an embodiment of the present invention.

FIG. 2B is a plot illustrating the Raman spectrum for the multilayer graphene structure shown in FIG. 2A.

FIG. 2C is a plot illustrating the XPS spectrum for the multilayer graphene structure shown in FIG. 2A.

FIG. 2D is a plot illustrating the UPS spectrum for the multilayer graphene structure shown in FIG. 2A.

FIG. 2E is a plot illustrating the Raman spectrum for samples using differing methane:hydrogen partial pressures according to an embodiment of the present invention.

FIG. 2F is a plot illustrating the Raman spectrum for samples using differing power densities according to an embodiment of the present invention.

FIG. 3A is an SEM image of graphene sheets grown on silicon according to an embodiment of the present invention.

FIG. 3B is a cross-sectional height measurement taken along line a illustrated in FIG. 3A.

FIG. 3C is a cross-sectional height measurement taken along line b illustrated in FIG. 3A.

FIG. 3D is a cross-sectional height measurement taken along line c illustrated in FIG. 3A.

FIG. 4A is an SEM image of three graphene sheets grown on silicon according to an embodiment of the present invention.

FIG. 4B is a cross-sectional height measurement taken across the graphene/silicon boundary of the three graphene sheets shown in FIG. 4A.

FIG. 4C is an SEM image of fourteen graphene sheets grown on silicon according to an embodiment of the present invention.

FIG. 4D is a cross-sectional height measurement taken across the graphene/silicon boundary of the fourteen graphene sheets shown in FIG. 4A.

FIG. 5A is a plot illustrating friction as a function of applied normal force for graphene sheets according to an embodiment of the present invention.

FIG. 5B is a plot illustrating friction as a function of the number of graphene layers for a first normal force according to an embodiment of the present invention.

FIG. 5C is a plot illustrating friction as a function of the number of graphene layers for a second normal force according to an embodiment of the present invention.

FIG. 5D is a plot illustrating friction as a function of the number of graphene layers for a third normal force according to an embodiment of the present invention.

FIG. 6 is a plot illustrating the Raman spectrum for graphene grown on a silicon dioxide substrate according to an embodiment of the present invention.

FIG. 7 is a plot illustrating the Raman spectrum for graphene grown on a diamond like carbon substrate according to an embodiment of the present invention.

FIG. 8A is a plot illustrating carbon monoxide gas pressure as a function of time for graphene growth processes on different substrates according to an embodiment of the present invention.

FIG. 8B is a plot illustrating carbon dioxide gas pressure as a function of time for graphene growth processes on different substrates according to an embodiment of the present invention.

FIG. 9A is an SEM image of vertical graphene nano-walls on a silicon substrate according to an embodiment of the present invention.

FIG. 9B is an enlarged image of a portion of the SEM image shown in FIG. 9A.

FIG. 9C illustrates optical micrographs of the silicon substrate before and after the growth of the vertical graphene nano-walls illustrated in FIG. 9A.

FIG. 9D is a plot of optical transmission as a function of wavelength for the vertical graphene nano-walls illustrated in FIG. 9A.

FIG. 9E is a plot illustrating the Raman spectrum for the vertical graphene nano-walls shown in FIG. 9A.

FIG. 9F is a plot illustrating the XPS spectrum for the vertical graphene nano-walls shown in FIG. 9A.

FIG. 9G is a plot illustrating the UPS spectrum for the vertical graphene nano-walls shown in FIG. 9A.

FIG. 10A is an SEM image of vertical graphene nano-walls grown on a silicon dioxide substrate according to an embodiment of the present invention.

FIG. 10B is an SEM image of vertical graphene nano-walls grown on a diamond like carbon substrate according to an embodiment of the present invention.

FIG. 11 is a simplified schematic diagram illustrating a PECVD graphene growth system according to an embodiment of the present invention.

FIG. 12 is a simplified flowchart illustrating a method of growing a plurality of graphene sheets according to an embodiment of the present invention.

### DETAILED DESCRIPTION OF SPECIFIC EMBODIMENTS

Graphene, a monolayer of carbon atoms forming a two-dimensional honeycomb structure, is known for its extraordinary electronic, optical, thermal, magnetic and mechanical properties. Recently, various research groups have demonstrated that mesoscale graphite, which consists of many layers of graphene, offers superior properties as a solid lubricant that is promising for significantly reducing the wear and energy consumption in mechanical systems. The structural superlubricity of graphite may be attributed to the weak van der Waals (vdW) interaction of graphene layers with most materials and the lateral mechanical stiffness of graphite when it forms incommensurable rigid crystalline contacts with most solid surfaces. Nevertheless, the aforementioned beneficial properties of graphite may not be realizable in the case of monolayer graphene because the morphology and characteristics of the substrate that supports the monolayer graphene will likely play a significant role in determining the friction between the monolayer graphene and other material surfaces. Another major challenge associated with the realization of superlubricity is its scalability. Namely, superlubricity will be reduced or cease to exist when the contact area scales up to the extent where disorder and imperfections become unavoidable. Thus, most superlubricity reported to date has only been achieved for submicron-scale contact areas.

A feasible remedy for the aforementioned issue is to deposit multilayer large-area graphene sheets on substrates to provide ultra-low friction for sliding. Although the contact between the sliding object and multilayer graphene may not be as perfect as atomically flat monolayer graphene, any deformation from the substrate can be considerably damped by the graphene layers if the thickness of multilayer graphene exceeds a characteristic penetration depth. This approach is therefore expected to result in an almost identical condition on the very top layer of the graphene sheets independent of the substrate effects, which may serve as a promising solution to overcome the scalability problem for real-world applications.

Another critical issue for using graphene as a solid lubricant is related to the complicated and time-consuming transfer processes. The most common technique for transferring graphene from its growth substrate to a target substrate involves a polymer-supported method, which always leads to polymer residues on the transferred graphene surfaces and therefore degraded performance of the graphene-incorporated devices. Other transfer methods without using polymers also involve multiple procedures such as copper etching, solution transfer, residue removal, and annealing, which generally lead to compromised graphene quality. Therefore, it is highly desirable to explore direct growth of graphene on common substrates, such as silicon, for better integration of graphene into current industrial technology.

To date, there have been few reports for the techniques of direct graphene growth on silicon. Among the limited studies, all have involved high-temperature (from 900° C. to 1550° C.) growth processes, and the resulting products are typically small graphene islands/flakes. In order to address these shortcomings, the inventors have developed a new scalable method by means of plasma enhanced chemical vapor deposition (PECVD) to directly grow graphene with full coverage on large-area (˜1 cm²) substrates of silicon (Si), silicon dioxide (SiO₂), or diamond-like carbon (DLC) without the need of active heating. As will be evident to one of skill in the art, high-temperature growth processes, for example, growth processes that result in a substrate temperature greater than about 520° C., are incompatible with CMOS processing.

As is well known to one of skill in the art, CMOS compatible processes are characterized by clear requirements related to 1) the chemicals that are used during processing and 2) the maximum processing temperature of 520° C. These requirements on chemistry and temperature are implemented in order to prevent damage to existing CMOS electronics that would occur if, for example, the processing temperatures exceed 520° C. Examples of such damage include degradation in interconnect sheet resistance, modification of dielectric layer permittivity, and the like.

The chemistry utilized according to embodiments of the present invention, including gaseous carbon containing precursors such as methane and carrier gases such as hydrogen are CMOS-compatible chemicals. The maximum temperature associated with CMOS compatible processes is described in Section 5.1 of Ann Witvrouw, Maria Gromova, Anshu Mehta, Sherif Sedky, Piet De Moor, Kris Baert, Chris van Hoof “Poly-SiGe, a superb material for MEMS,” Proc Mat. Res. Soc. 782 (2004) 25-36. As discussed therein, if processing operations are to be CMOS compatible, the maximum fabrication temperature is limited because of the risk to damage existing electronics and/or degrade their performance. Most standard CMOS processes are capable of withstanding post-processing temperatures of 450-520° C. Thus, for purposes of this application, CMOS compatible processes, including graphene growth in a PECVD growth chamber, include processes in which the substrate temperature is limited to 520° C.

Thus, since high-temperature growth processes utilize temperatures that exceed the acceptable temperature range (<˜520° C.) for existing fabrication technology employed by the semiconductor industry, conventional, high-temperature graphene growth processes are rendered impractical for integration with silicon processing. Thus, embodiments of the present invention provide methods and systems that achieve direct growth of graphene on silicon that are compatible with current Si-CMOS manufacturing technology, that is, are CMOS-compatible processes.

Systematic friction studies of graphene multilayers on silicon further indicate that ultra-low friction approaching the superlubricity limit has been achieved at the micrometer scale. Given the importance of silicon in modern technologies, the methods of direct and scalable graphene growth on silicon discussed herein promise a path towards integrating graphene into silicon-based technologies for applications ranging from various optoelectronics to energy storage including next-generation lithium-ion batteries, and structural superlubricity.

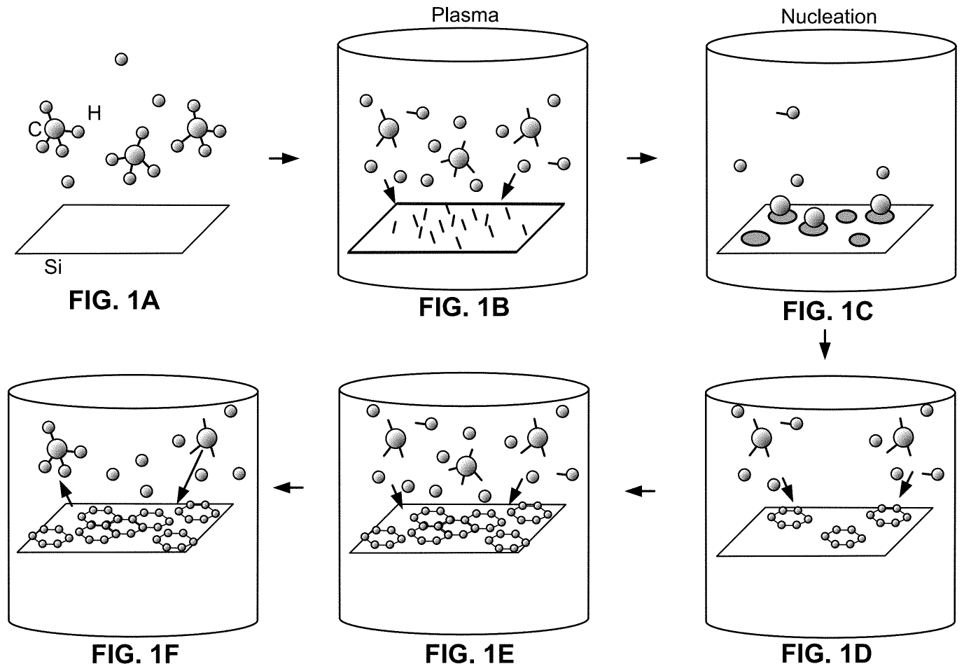

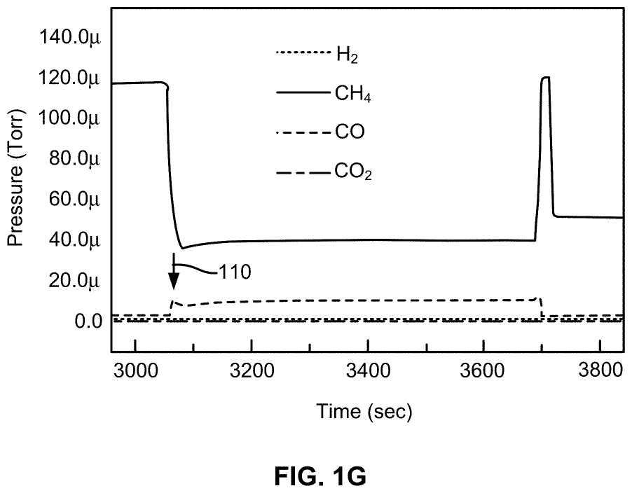

FIGS. 1A-1F are schematic diagrams illustrating the graphene growth process according to an embodiment of the present invention. As illustrated in FIG. 1A, the initial environment inside the growth chamber before igniting the plasma source provides an environment filled with CH₄ and H₂ as a result of flow of methane as a carbon precursor and hydrogen as a carrier gas into the growth chamber. Oxygen is also present in the environment since oxygen is present on the substrate surface in the form of a native oxide for the silicon substrate in the illustrated embodiment. Although hydrofluoric acid (HF) had been applied to remove the surface SiO₂ and to passivate the surface of the silicon substrate by hydrogen immediately before inserting the silicon substrate into the growth chamber, some degree of native oxide formation occurs. In addition to silicon-oxygen bonds on the silicon substrate surface, the silicon surface also includes hydrogen-terminated silicon bonds.

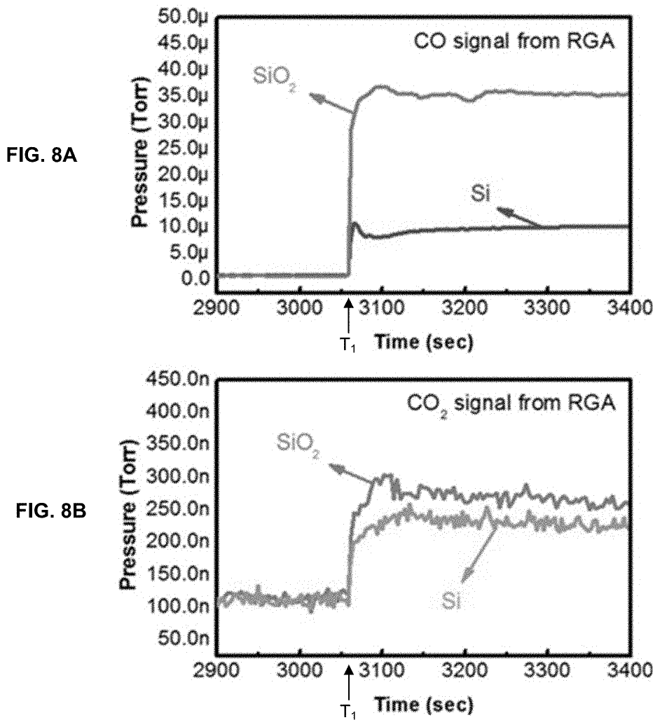

FIG. 1B corresponds to the plasma ignition state. After ignition of the plasma, and given the environment in the growth chamber, carbon and oxygen start to disassociate from CH₄ and SiOₓ, respectively. In other words, after turning on the plasma, both the surface Si—O and Si—H bonds as well as the C—H bonds in methane were broken by energetic radicals in the plasma so that most of the oxygen atoms reacted with carbon atoms and formed carbon monoxide, as schematically illustrated in FIG. 1B and discussed more fully in relation to FIG. 1G, which shows the empirical verification of carbon monoxide production based on the RGA record. As discussed in relation to FIG. 1G, the RGA record indicated a notable increase of CO after the plasma was ignited at a time of ˜3075 seconds as indicated by arrow 110. Similar studies were also conducted on the PECVD growth of graphene on SiO₂ substrates, which revealed even stronger CO signals from the RGA as shown in FIG. 8A and further confirmed that surface oxides were removed by plasma during the growth process. For both silicon and SiO₂ substrates, we noted that the increase of CO₂ was far less than CO, which may be attributed to the limited surface native oxides, although the elevation of the CO₂ signal for the PECVD growth of graphene on SiO₂ substrates after igniting the plasma was still higher than that for the growth on silicon substrates due to more surface oxides in the former, as shown in FIG. 8B. It is important to note that the pressures monitored by the RGA is several orders of magnitude less than the pressure of the growth chamber to which the RGA is attached.

In FIG. 1C, nucleation of carbon on the substrate begins taking place. The removal of surface Si—O and Si—H bonds resulted in many surface silicon dangling bonds, which were highly reactive and so could adhere carbon atoms in the plasma to nucleate graphene growth on the silicon surface, as depicted in FIG. 1C. This growth model is consistent with the precipitous drop of CH₄ pressure in the RGA spectra upon igniting the plasma as shown in FIG. 1G. Continuous CH₄ supply, together with active carbon decomposition and reactive silicon surface dangling bonds, contributed to the ensuing growth of graphene over the entire substrate, as schematically shown in FIGS. 1D and 1E. In FIG. 1E, the formation of stacking graphene sheets or vertical graphene nano-walls occurs. Horizontal graphene sheets initially started to extend along the in-plane direction from various nucleation centers. With continuing growth time, new graphene sheets began to develop from the silicon surface due to the relatively weak interaction between graphene and silicon, which elevated the already grown graphene sheets and stacked into multilayers.

As described more fully herein, proper control of the plasma power and the carbon supply are utilized to form the stacked graphene sheets and/or vertical graphene nano-walls. Of particular note, the inventors have determined that for sufficiently high plasma power and CH₄ supply, vertical graphene nano-walls rather than horizontal graphene sheets would predominantly grow from silicon substrates. Without limiting embodiments of the present invention, the inventors believe that in addition to the removal of surface Si—O and Si—H bonds, highly energetic radicals in the plasma could also create numerous small craters on the surface of silicon substrate, which may favor vertical growth of graphene nano-walls from the craters in the presence of excess free carbon atoms.

In FIG. 1F, two dynamic processes are illustrated: graphene deposition and carbon etching. During the PECVD growth processes, the in-plane propagation of graphene deposition could always be terminated by the formation of C—H bonds and/or carbon etching by energetic radicals in the hydrogen plasma. Therefore, as shown in FIG. 1F, proper control of the CH₄/H₂ ratio to balance the two dynamic processes of graphene deposition and carbon etching plays an important role in this PECVD growth of graphene. Additionally, the presence of energetic radicals to remove surface oxides from silicon and to extract carbon from CH₄ during the PECVD growth process is a key factor that facilitates the deposition of graphene on silicon in contrast to traditional thermal CVD methods.

FIG. 1G is a plot illustrating gas flow rates prior to, during, and after a graphene growth process according to an embodiment of the present invention. In this plot, a residual gas analyzer (RGA) is utilized to provide a record of different gases in the growth chamber over a time period of approximately 10 minutes. In FIG. 1G, the plasma is ignited at a time of ˜3075 seconds as indicated by arrow 110. As illustrated in FIG. 1G, the production of CO₂, CO, and H₂O are evidence of the removal of the native oxide on the silicon substrate by the predetermined microwave plasma power density and carbon source density.

Based on the experimental results and data discussed herein and the RGA data illustrated in FIG. 1G, the inventors have developed, without limiting embodiments of the present invention, the growth mechanism of graphene on silicon, including nucleation processes and plasma effect, discussed in relation to FIGS. 1A-1F.

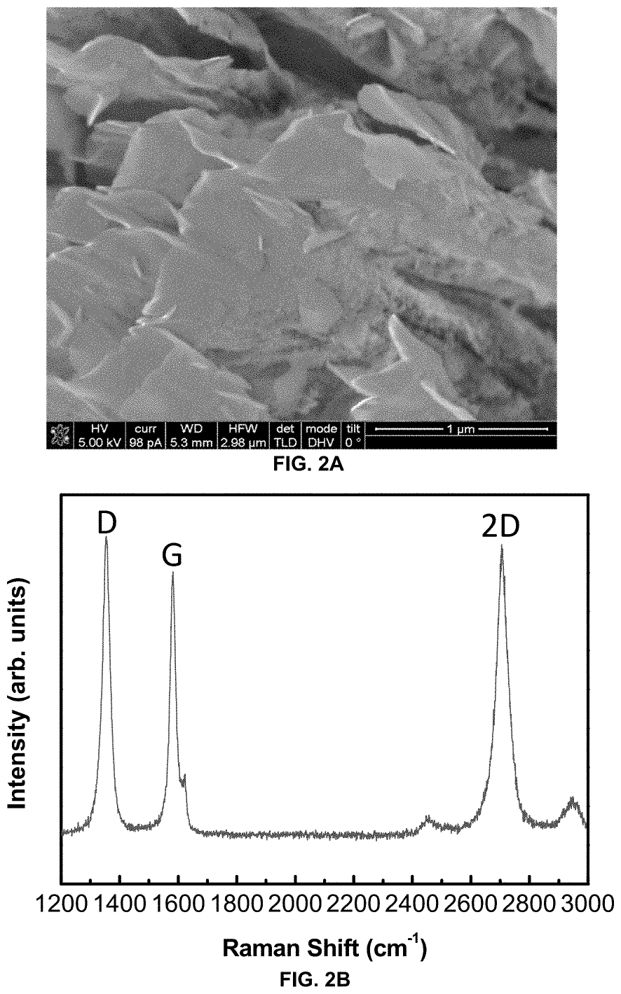

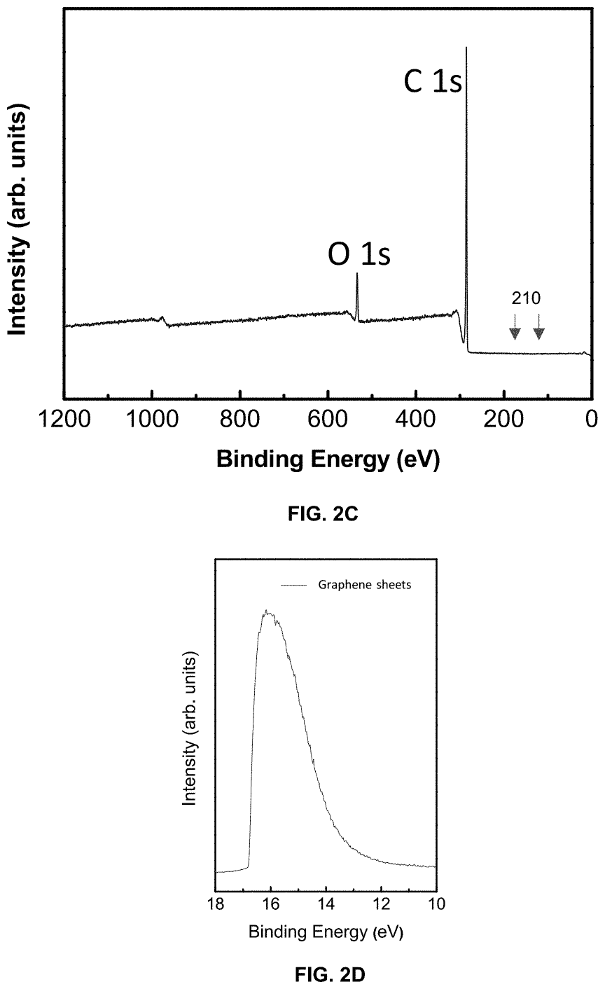

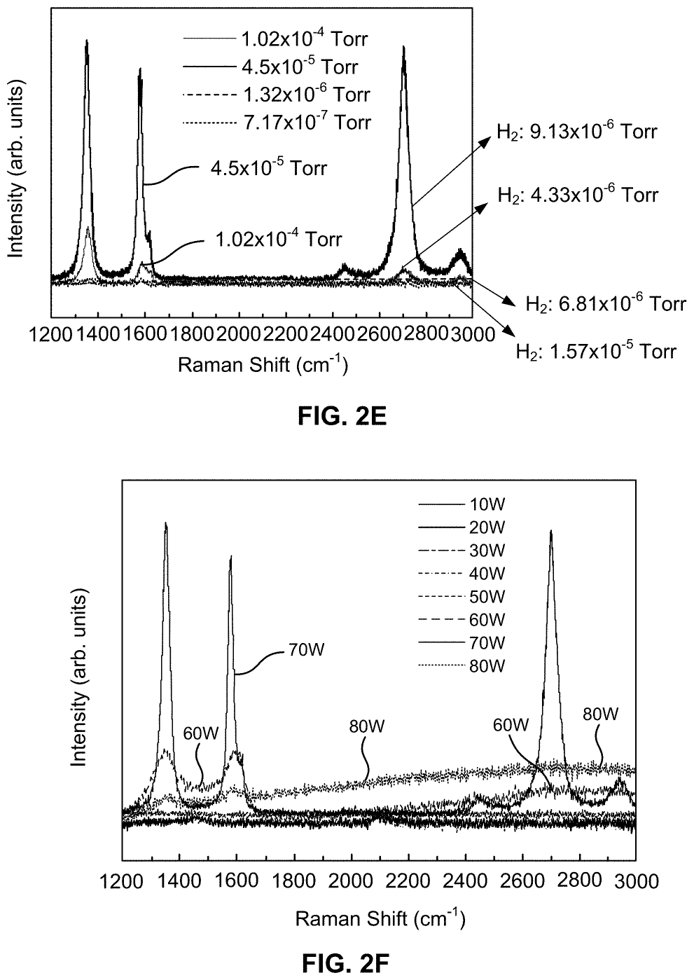

FIG. 2A is a scanning electron microscope (SEM) image of a multilayer graphene structure fully covering a silicon substrate according to an embodiment of the present invention. SEM images were taken using an FEI Nova 600 NanoLab. In comparison with conventional techniques, which produce nanometer-scale grains, embodiments of the present invention produce micron-scale grain sizes. In FIG. 2A the SEM image of as-grown graphene sheets shows full coverage of the underlying silicon substrate after only 10 minutes of PECVD growth. For this PECVD growth process, the chamber base pressure was 2.33×10⁻² Torr before flowing in process gases. RGA measurements indicate that a CH₄ pressure of 4.58×10⁻⁵ Torr, a N₂ pressure of 3.75×10⁻⁷ Torr, and a H₂ pressure of 9.09×10⁻⁶ Torr were utilized during the growth process. These pressures measured using RGA indicate that the growth chamber pressure (approximately 500 mTorr) was approximately 10,000 and 50,000 times higher than the measured CH₄ and H₂ partial pressures, respectively, in the RGA for these processing conditions. As shown in FIG. 2A, the graphene sheets were multilayer graphene with full coverage all over the surface of the silicon substrate (˜1 cm²). The SEM image indicates that the as-grown graphene layers generally exhibit multi-domain distributions with varying thicknesses. The lateral dimension of each graphene layer is typically much larger than 1 μm although it is difficult to identify the borders associated with individual sheets because they mostly overlap on each other.

To characterize the quality of the graphene multilayers grown on silicon substrates, the inventors performed Raman spectroscopic studies on various random areas over each sample and found consistent spectra throughout, implying uniform quality of the as-grown graphene multilayers on Si.

FIG. 2B is a plot illustrating the Raman spectrum for the multilayer graphene structure shown in FIG. 2A. Raman spectra were obtained via a Renishaw M1000 micro-Raman spectrometer system using a 514.3 nm laser (2.41 eV) as the excitation laser source. As shown in FIG. 2B, the representative Raman spectrum taken on a sample of multilayer graphene-on-silicon reveals typical graphene Raman modes of the 2D, G- and D-bands with narrow FWHM. The intensity of the 2D-band at (2696±2) cm⁻¹ in the Raman spectrum is larger than that of the G-band at (1583±2) cm⁻¹, and an intense D-band at (1615±2) cm⁻¹ was also observed due to the presence of many boundaries around the edges of graphene sheets, i.e., the presence of graphene edges associated with multi-domain graphene sheets on the surface.

Additional characterizations of the physical and chemical properties of the graphene-covered silicon samples were investigated by X-ray and ultraviolet photoemission spectroscopy (XPS and UPS). XPS and UPS were conducted via the Kratos-Ultra-XPS model, which employed a magnetic immersion lens with a spherical mirror and concentric hemispherical analyzers with a delay-line detector for both imaging and spectroscopy. Al Kα (1.486 keV) monochromatic X-rays and He I (21.2 eV) were used as the excitation sources for XPS and UPS measurements, respectively, in an ultrahigh vacuum chamber with a base pressure lower than 2×10⁻¹⁰ Torr. Transmission spectra were collected using a Cary 5000 absorption spectrometer with an integrating sphere. Quartz substrates were used as the supporting object for the measurements.

FIG. 2C is a plot illustrating the XPS spectrum for the multilayer graphene structure shown in FIG. 2A. The XPS spectrum in FIG. 2C revealed a clean sample surface with only C-1s and O-1s signals. The dominant C-1s peak (>95%) was from the as-grown graphene multilayers, whereas the presence of a small O-1s peak (<5%) may be the result of broken Si—O bonds from the substrate surface, which is further elaborated in the context of growth mechanism. Thus, the chemical purity of the PECVD-grown graphene sheets was confirmed since the XPS spectrum revealed only C-1s and O-1s peaks, and the O-1s peak intensity indicated that the oxygen content on the surface was less than 5% relative to carbon, suggesting that the surface composition was predominately carbon. In particular, we note that no Si peaks could be found in the XPS spectrum at binding energies between about 100 and 200 eV, noted as region 210, which implied full coverage of graphene on the silicon substrate and further corroborates the finding from the SEM image in FIG. 2A.

FIG. 2D is a plot illustrating the UPS spectrum for the multilayer graphene structure shown in FIG. 2A. The work function of the graphene layers was examined through UPS and the result shown in FIG. 2D. The value deduced from the secondary electron cutoff of the UPS spectrum was (4.45±0.05) eV, which was in good agreement with the typical value of the work function pristine graphene without doping.

FIG. 2E is a plot illustrating the Raman spectrum for samples using differing methane:hydrogen partial pressures according to an embodiment of the present invention. In addition to the range of microwave power densities discussed in relation to FIG. 2F, the carbon source utilized by embodiments of the present invention, in this series of conditions, methane, is provided at levels sufficient to react with oxygen produced by decomposition of the native oxide and remove oxygen from the growth chamber. As illustrated in FIG. 2E, the methane partial pressure, as measured by RGA, was varied between 10⁻⁴ Torr and 10⁻⁷ Torr. The partial pressures illustrated in FIG. 2E were measured using the RGA, which provides pressure measurements approximately 1,000 to 10,000,000 times smaller than the actual growth chamber pressure. Thus, the partial pressures in the growth chamber are approximately 1,000 to 10,000,000 times larger than the measured RGA partial pressures. For all methane partial pressures, the PECVD power density was set at 70 W/cm³. The hydrogen partial pressure was measured using the RGA in conjunction with the methane partial pressure, utilized in each condition. Table 1 provides the gas partial pressures, the ratio of methane to hydrogen partial pressure, and the result achieved for each of the processing conditions.

TABLE 1

| Gas (Partial | | | | |
|---|---|---|---|---|
| Pressure) | Condition 1 | Condition 2 | Condition 3 | Condition 4 |
| CH₄ | 7.17 × 10⁻⁷ Torr | 1.32 × 10⁻⁶ | 4.5 × 10⁻⁵ | 1.02 × 10⁻⁴ |
| | | Torr | Torr | Torr |
| H₂ | 1.57 × 10⁻⁵ Torr | 6.81 × 10⁻⁶ | 9.13 × 10⁻⁶ | 4.33 × 10⁻⁶ |
| | | Torr | Torr | Torr |
| CH₄:H₂ | 0.05 | 0.19 | 4.9 | 23.6 |
| Result | No graphene | No graphene | Graphene | Graphene |
| | | | Sheets | nano-walls |

Thus, in a manner similar to the range of PECVD power densities associated with graphene growth, a range of CH₄:H₂ ratios were suitable for graphene growth. The inventors believe, without limiting embodiments of the present invention, that at low CH₄:H₂ ratios, for example, less than 0.15, the volume of methane present in the growth chamber is not sufficient to fully remove the native oxide from the silicon surface. Thus, although some portions of the substrate may support graphene growth, resulting in partial coverage, full coverage by graphene does not occur.

In addition to the partial pressures illustrated in Table 1, the inventors performed additional processing runs under additional conditions. High quality graphene sheets were fabricated using Condition 3 as illustrated by the Raman spectrum marked as 4.5×10⁻⁵ Torr in FIG. 2E. When the methane partial pressure measured using RGA was reduced to 4.1×10⁻⁵ Torr, the 2D-band Raman peak was reduced in intensity. Furthermore, when the methane partial pressure dropped below 4×10⁻⁵ Torr, the 2D-band, G-band, and D-band peaks decreased in intensity rapidly with decreasing methane partial pressure. The inventors thus determined that methane partial pressures of approximately 3×10⁻⁵ Torr provided a lower bound for graphene growth similar to Condition 3. For these graphene growth conditions, the H₂ partial pressures ranged from 8.5×10⁻⁶ Torr to 1.5×10⁻⁵ Torr. Therefore, the inventors have determined that methane partial pressure to hydrogen partial pressure ratios in a range between ˜3 and ˜5.5 are associated with growth of multilayer sheets of graphene.

Thus, growth of graphene on silicon is enabled by a predetermined range of PECVD power densities and a predetermined range of carbon precursor to carrier gas ratios. In order to create silicon dangling bonds suitable for carbon nucleation, PECVD power densities in a range between ˜60 W/cm³ to ˜80 W/cm³ were utilized. At lower powers, for example, powers utilized for the growth of graphene monolayers on copper, the plasma did not remove the native oxide on the silicon surface, thereby preventing graphene growth. Additionally, sufficient levels of methane are utilized to react with oxygen present in the native oxide and form gaseous byproducts (e.g., CO, CO₂, H₂O) that can be evacuated from the growth chamber. Thus, a predetermined range of CH₄:H₂ ratios ranging from 0.15 to 5.5 were utilized to growth graphene sheets on silicon substrates. As methane levels were increased over this range, the graphene growth transitioned to vertical graphene nano-walls as discussed herein. It should be noted that in Condition 4 (graphene nano-walls), the 2D-band intensity decreased with respect to the value measured for Condition 3 (graphene sheets), which is consistent with reduced intensity 2D-band peaks observed for graphene nano-walls.

FIG. 2F is a plot illustrating the Raman spectrum for samples using differing power densities according to an embodiment of the present invention. As illustrated in FIG. 2F, the PECVD power was varied between 10 W and 80 W, resulting in a power density ranging from 10 W/cm³ to 10 W/cm³ for the plasma volume of ˜1 cm³. For all PECVD powers, the methane partial pressure was 10⁻⁵ Torr and the hydrogen partial pressure was 9×10⁻⁶ Torr, with both of these partial pressures being measured RGA readings. As discussed in relation to FIG. 2E, these partial pressures were utilized based on Raman measurements made over a range of partial pressures.

At low PECVD power, no evidence of graphene is observed as indicated by the Raman spectra associated with 10 W through 50 W. When the PECVD power was increased to 60 W, graphene Raman modes of the G- and D-bands with broad FWHM began to be observed. Thus, at a power density of 60 W/cm³, graphene growth occurred. At a PECVD power of 70 W, graphene Raman modes of the 2D-, G-, and D-bands with narrow FWHM were observed as high quality graphene multilayer structures were produced. As the PECVD power was increased to 80 W, the graphene Raman modes of the 2D-, G-, and D-bands with broad FWHM were observed again, indicating that graphene growth was being terminated at high power.

The inventors have, therefore, determined that a relatively narrow window of PECVD power densities corresponds to graphene growth conditions. The inventors have determined that growth of graphene on silicon is enabled by removal of the native oxide layer present on silicon. Low PECVD powers, for example, 40 W/cm³ that is utilized for the growth of graphene monolayers on copper, is not sufficient to grow graphene on silicon because the plasma power is not sufficient to remove the native oxide that is present on the silicon surface. Using the microwave plasma, embodiments of the present invention remove the native oxide layer to produce dangling bonds at the silicon substrate surface. Because of the bond strength of silicon dioxide is high, a microwave plasma power sufficient to decompose the silicon dioxide native oxide into oxygen and silicon dangling bonds is utilized. Thus, graphene growth on silicon utilizes a PECVD power density that is approximately twice the PECVD power density utilized to grow monolayer graphene on copper.

As illustrated in FIG. 2F, a microwave power density in a range from ˜60 W/cm³ to ˜80 W/cm³, for example, ˜70 W/cm³, is utilized in some embodiments. Thus, once the microwave plasma has been utilized to remove the native oxide and expose the silicon surface, carbon can bond to the dangling silicon bonds to initiate the growth of the graphene layers. In fact, the inventors have determined that lower power microwave plasmas, which have been previously utilized in growing graphene on copper substrates, for example, microwave power densities in the range of 40 W/cm³ are insufficient to remove the native oxide present on silicon substrates. Although these lower microwave power densities are sufficient, given the appropriate process gases, to remove the oxide present on copper surfaces, these lower power densities are not sufficient to remove native oxide present on silicon substrates and create dangling silicon bonds suitable for initiating growth of graphene films. The inventors have also determined that as the microwave power density is increased, the energetic species in the plasma can damage the graphene that is grown at lower power densities. Thus, a predetermined range of microwave powers are bounded by a power that is high enough to remove the native oxides and enable graphene growth and a power that is low enough to not damage the graphene as it grows. Accordingly, the balance between these opposing processes results in a PECVD power density range of ˜60 W/cm³ to ˜80 W/cm³ that is utilized as described herein.

The method that we disclose here for graphene growth on silicon by means of PECVD is very different from all other methods developed to date because more energetic and reactive environments can be provided by plasma at a relatively low temperature (<520° C.). Since oxidized silicon surface is very inert, our approach to first removing SiO₂ from the silicon surface and then passivating the surface dangling bonds by hydrogenation made it feasible for using energetic particles and UV light in the plasma to remove the relatively weak silicon-hydrogen bond and then activate the reaction of silicon dangling bonds with carbon radicals in the plasma without the need of elevated temperatures. Furthermore, plasma could provide sufficiently high energy to grow graphene vertically in the presence of high concentrations of carbon sources within a short time period (˜10 minutes).

Our successful demonstration of single-step direct PECVD growth of graphene on large-area silicon substrates with full coverage opens up a new pathway towards novel optoelectronic applications that are based on intimate integration of graphene and silicon, such as atomically thin transistors and biosensors. Using conventional methods, any integration of graphene and silicon would require using polymers to assist transfer of graphene onto silicon substrates. Given that residues from polymers could not be fully removed and would always result in degraded device performance and lack of controllability, the need of graphene transfer process is clearly not desirable. Thus, our demonstration of direct growth of high-quality graphene on silicon provides unprecedented opportunities for developing high-quality, reliable and reproducible devices based on integrated graphene and silicon.

To investigate the surface morphology (e.g., the degree of surface flatness) and thickness of the as-grown graphene layers on silicon, tapping mode atomic force microscopy (AFM) was conducted on a silicon substrate both before and after graphene growth.

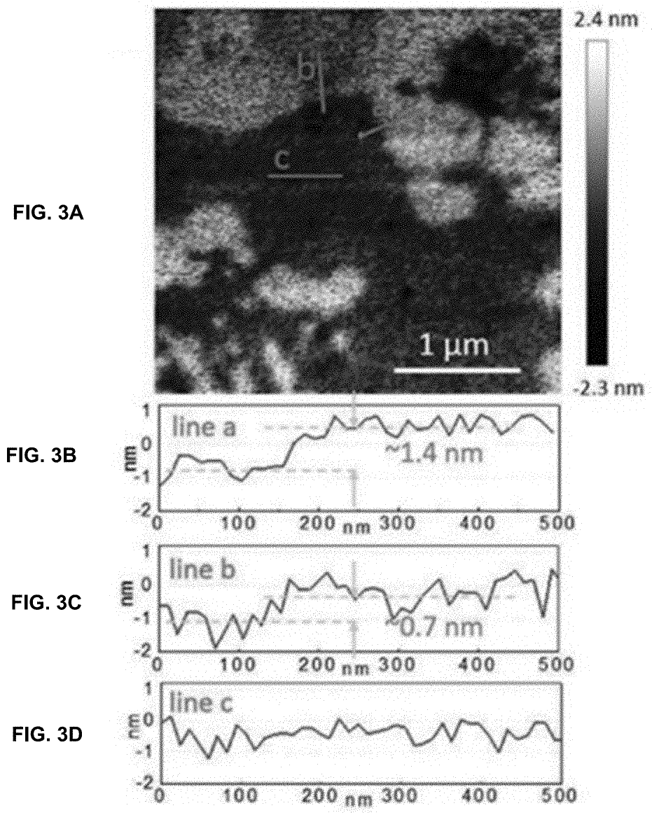

FIG. 3A is an SEM image of graphene sheets grown on silicon according to an embodiment of the present invention. As illustrated in FIG. 3A, the high-sensor AFM image of the graphene-covered silicon surface revealed multiple domains with varying heights throughout the micrometer-scale area. The layered structures on the surface were the as-grown graphene sheets with an averaged lateral dimension larger than 1 μm. The thickness of the sheets was examined by studying the cross-sectional profiles. In particular, cross-sectional profiles were obtained and demonstrated different domains with different step heights as illustrated by the cross-sections along line a and line b.

FIG. 3B is a cross-sectional height measurement taken along line a illustrated in FIG. 3A. FIG. 3C is a cross-sectional height measurement taken along line b illustrated in FIG. 3A. FIG. 3D is a cross-sectional height measurement taken along line c illustrated in FIG. 3A.

Referring to FIG. 3B, the cross-section along line a showed a ˜0.7 nm step that corresponded to two layers of graphene thickness. As shown in FIG. 3C, the cross-section along line b revealed a ˜1.4 nm step that corresponded to 4 layers of graphene. These results therefore suggested that the surface consisted of integer numbers of graphene layers within the resolution of the AFM, which were also in agreement with the SEM image shown in FIG. 1A. More importantly, it should be noted that along line c, the cross-section of which is illustrated in FIG. 3D, the absence of discernible height variations within instrumentation resolution suggested that the profile was taken on an atomically flat surface. Such atomically flat regions were found to have a lateral dimension larger than a few to tens of micrometers, suggesting that the individual graphene layers grown on silicon by the PECVD method were several orders of magnitude larger than the sub-micrometer scale flakes obtained by conventional methods.

In addition to understanding the surface topography of graphene-covered silicon substrate, we performed the same studies on a bare silicon surface as a reference for comparison. From the cross-sectional profiles, we found that the roughness of the silicon surface was mostly within 1 nm. However, a few pits with depths larger than 1 nm were found. Additionally, sharp particles with heights taller than 1 nm were observed in the cross-sectional profiles. Combining the findings from these baseline analyses and the AFM results for graphene on silicon substrates, the inventors believe, without limiting embodiments of the present invention, that the as-grown graphene layers can effectively smooth out small pinholes and deposits on the silicon surface, resulting in reduced roughness as exemplified by the relatively flat morphology along line c on the graphene covered surface shown in FIG. 3. The reduction of surface roughness can contribute to lower sliding friction, which has been independently verified by studies of the friction and will be discussed more fully herein.

AFM images and friction measurements were performed on a Bruker Dimension Icon AFM. Two modes of AFM were used: the tapping mode and the contact mode. The tapping mode was used to acquire the surface morphology and the contact mode was used to analyze the frictional force. For the friction measurements, a triangular cantilever made of SiN and coated with reflective gold (Bruker DNP-10) was used for the lateral force microscopy (LFM) tests. The thickness, length, width, and spring constant of the cantilever were 0.6 m, 205 m, 25 m, and 0.06 N/m, respectively. The height and radius of the tip on the cantilever were 5.5 m and 20 nm, respectively. To extract the applied normal force from the voltage signal of the AFM system, the following formula was used: Normal force (N)=[voltage (V)]×[deflection sensitivity (nm/V)]×[spring constant (N/m)]. The deflection sensitivity was calibrated every time by doing a force-curve scan before the friction measurements. To convert the measured voltage signal to the friction force, the following formula was applied:

$${K}_{L} = \frac{{GWt}^{3}}{3 L} {( \frac{1}{h + t \text{/} 2} )}^{2} ,$$

Here h is the height of the tip, L is the length of the cantilever, V is the measured voltage signal, S_{Dif} is the deflection sensitivity, and the K_{L} is given by the following expression:

$$f = \frac{0.4 {hK}_{L} V}{{LS}_{Dif}}$$

where G is the shear modulus (=1.69×10¹¹ Pa), w is the width of the cantilever, and t is the thickness of the cantilever.

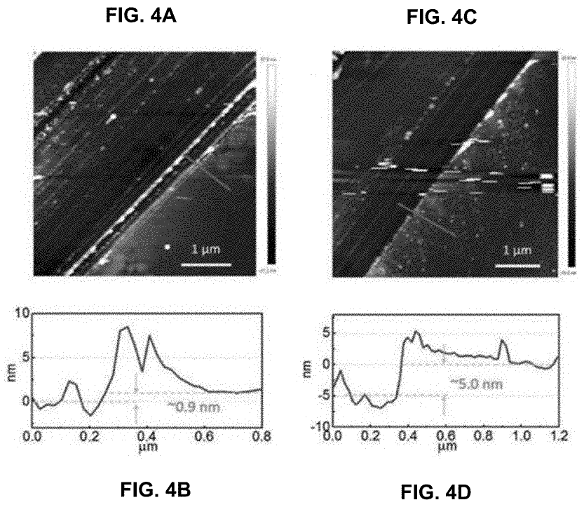

FIG. 4A is an SEM image of three graphene sheets grown on silicon according to an embodiment of the present invention. FIG. 4B is a cross-sectional height measurement taken across the graphene/silicon boundary of the three graphene sheets shown in FIG. 4A.

FIG. 4C is an SEM image of fourteen graphene sheets grown on silicon according to an embodiment of the present invention. FIG. 4D is a cross-sectional height measurement taken across the graphene/silicon boundary of the fourteen graphene sheets shown in FIG. 4A.

Referring to FIGS. 4A and 4B and FIGS. 4C and 4D, respectively, the SEM and AFM can be utilized to characterize the cross-sectional profiles of 3 layers of graphene and 14 layers of graphene sheets grown on silicon substrates. For this analysis, a sharp AFM tip was used to make scratches on graphene surfaces for cross-sectional studies. Some overshoots were formed due to the method used to create scratches, and so the steps were determined by the mean heights at distances far from the cuts.

As shown in FIG. 4B, the cross-section showed a ˜0.9 nm step that corresponded to three layers of graphene thickness. As shown in FIG. 4D, the cross-section revealed a ˜5.0 nm step that corresponded to 14 layers of graphene.

To understand the effect of graphene layers on the friction of graphene-covered silicon surface, we used lateral force microscopy (LFM) of the contact-mode AFM to conduct surface friction studies as a function of the graphene thickness, applied normal force, and contact area.

To determine the number of graphene layers, we first estimated it by the intensity ratio of the 2D-to-G Raman modes, and then conducted cross-sectional AFM measurements to obtain a more accurate value as discussed in relation to FIGS. 4A-4D. Two thicknesses of graphene sheets with averaged values of 0.9 nm and 5 nm were investigated systematically, which corresponded to approximately 3 and 14 layers of graphene, respectively, given the resolution of AFM.

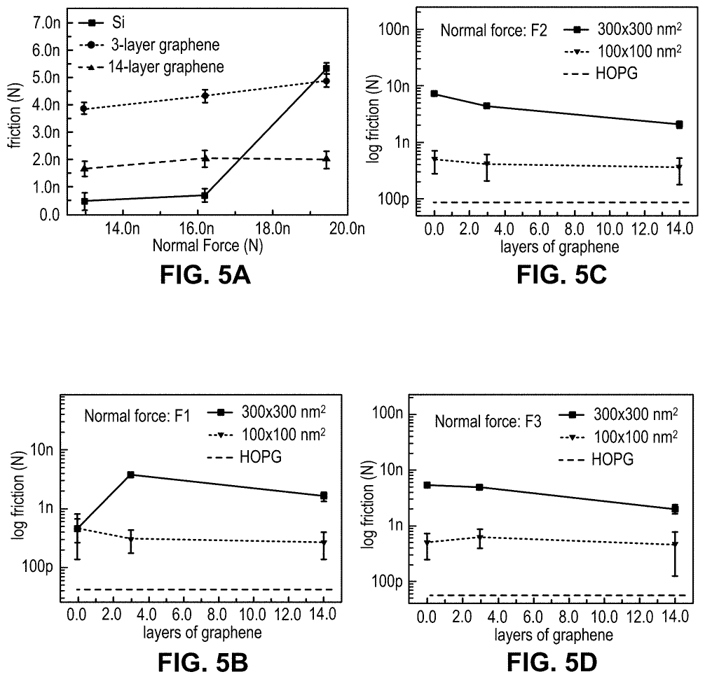

FIG. 5A is a plot illustrating friction as a function of applied normal force for graphene sheets according to an embodiment of the present invention. For the data shown in FIG. 5A, the friction between the AFM tip and the sample surface as a function of applied normal forces was averaged over a (300 nm×300 nm) area for bare silicon, 3 layers of graphene sheets, and 14 layers of graphene sheets. Without graphene coverage, the bare silicon surface exhibited a relatively low friction under a small normal force of F1=12.96 nN, but the friction increased rapidly when the normal force reached 19.44 nN. The dependence of friction on the normal force became very different for graphene-covered silicon surfaces. Namely, despite slightly larger frictions under smaller loads, both graphene-covered samples exhibited a much smaller increase in friction with the increasing load than the bare silicon surface. In particular, the silicon surface covered with 14 layers of graphene revealed the lowest friction for a normal force of F3=19.44 nN or larger, as shown in FIG. 5A. This finding suggests that a sufficiently large number of graphene layers on top of a substrate can mitigate the surface roughness effect of the underlying substrate, leading to significant reduction in the sliding friction.

Despite the apparent reduction in both the friction and the frictional coefficient with increasing graphene layers as shown in FIG. 5A, the lowest value of the frictional coefficient, 0.128 (=1.66 nN/12.96 nN), still fell outside the range of superlubricity, most likely because this data was collected over areas that included steps of graphene layers. Noting that typical measurements of superlubricity generally excluded areas with defects or edges, the scan region was downsized to an atomically flat area 100 nm×100 nm in size.

FIG. 5B is a plot illustrating friction as a function of the number of graphene layers for a first normal force according to an embodiment of the present invention. FIG. 5C is a plot illustrating friction as a function of the number of graphene layers for a second normal force according to an embodiment of the present invention. FIG. 5D is a plot illustrating friction as a function of the number of graphene layers for a third normal force according to an embodiment of the present invention.

Referring to FIG. 5B, the friction value (in log scale) as a function of the number of graphene layers was measured from both large (300 nm×300 nm) and small (100 nm×100 nm) scan areas under the same load of F1=12.96 nN. For comparison, the same measurements were also conducted on a piece of highly oriented pyrolytic graphite (HOPG), which represented results obtained from a number of graphene layers approaching infinity. The frictional coefficient of 0.0055 thus obtained from HOPG was consistent with a superlubricity surface, which further validated our experimental approach.

As illustrated in FIG. 5B, the sliding friction exhibited gradual decrease with increasing interfacial graphene layers for both scan areas. Moreover, friction obtained from the smaller area was more than one order of magnitude less than that obtained from the larger area. As will be described below, the smaller area reached an ultra-low frictional coefficient of ˜0.015 (=0.293 nN/19.44 nN) for normal force F3, which was approaching the superlubricity limit.

Referring to FIGS. 5C and 5D, similar friction measurements were carried out under larger loads (i.e., F2=16.20 nN in FIG. 5C and F3=19.44 nN in FIG. 5D). Both cases showed that surfaces with 14-layer graphene coverage displayed the lowest friction values when compared to those of either the pristine silicon surface or 3-layer graphene coverage. Furthermore, the trend of decreasing friction with increasing graphene layers for all loads is expected to approach the superlubricity value of HOPG (dotted lines) when the number of layers of graphene continues to increase. Our findings are consistent with recent theoretical calculations that demonstrate rapid damping of surface corrugations by misaligned layers of van der Waals materials. The inventors believe that the ultra-low frictional coefficient of ˜0.015 achieved using a load of F3=19.44 nN is the lowest measured coefficient of friction acquired between an AFM tip (with a radius ≤20 nm) and an as-grown graphene surface without using a lithographically fabricated graphite mesa as the sliding head.

Thus, the methods and systems for the PECVD direct growth of multilayer graphene on silicon described herein provide a scalable approach to product ultra-low friction surfaces and further opens up a pathway towards significantly reducing friction on a wide variety of substrates by multilayers of van der Waals materials with a thickness larger than the penetration depth of the surface corrugation of substrates.

Direct PECVD growth of graphene on SiO₂ and diamond-like carbon (DLC) substrates was also achieved with slightly different growth parameters. Thus, these results demonstrate that the methods and systems described herein are not limited to silicon substrates, but are also applicable to a broader category of substrates ranging from metallic to insulating materials. Merely by way of example, substrates that can be utilized in accordance with embodiments of the present invention include (100) single crystalline silicon substrates, polycrystalline silicon substrates, amorphous silicon layers on silicon layers, or silicon substrates with dielectric layers, for example, silicon oxide, silicon nitride, and the like.

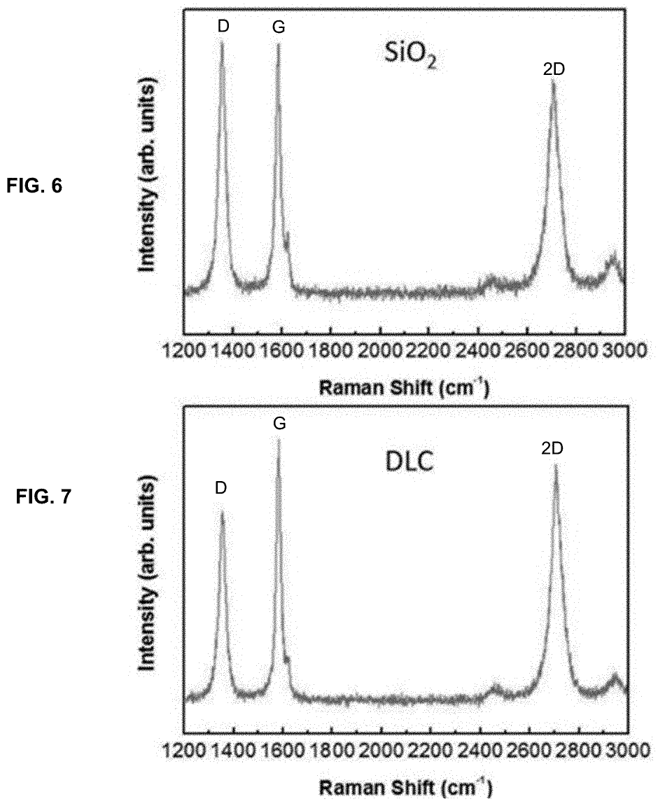

FIG. 6 is a plot illustrating the Raman spectrum for graphene grown on a silicon dioxide substrate according to an embodiment of the present invention. As illustrated in FIG. 6, multilayer graphene sheets grown on an SiO₂ substrate (e.g., a silicon substrate with a SiO₂ layer) are characterized by graphene Raman modes of the 2D, G- and D-bands with narrow FWHM. The intensity of the 2D-band at (2696±2) cm⁻¹ in the Raman spectrum is smaller than that of the G-band at (1583±2) cm⁻¹, and a D-band at (1615±2) cm⁻¹ with intensity approximately equal to the G-band was observed. This intense D-band is consistent with the presence of boundaries around the edges of graphene sheets, i.e., the presence of graphene edges associated with multi-domain graphene sheets on the surface.

FIG. 7 is a plot illustrating the Raman spectrum for graphene grown on a diamond like carbon substrate according to an embodiment of the present invention. In a manner similar to the Raman spectra for multilayer graphene on silicon and silicon dioxide substrates, the Raman spectrum for graphene on DLC includes Raman modes of the 2D, G- and D-bands with narrow FWHM. The intensity of the 2D-band at (2696±2) cm⁻¹ in the Raman spectrum is approximately equal to that of the G-band at (1583±2) cm⁻¹, and a D-band at (1615±2) cm′ with intensity less than the G-band was observed. As illustrated in FIG. 7, the D-band peak has a smaller intensity than the G-band peak. As will be evident to one of skill in the art, the smaller the D-band peak to the G-band peak, the larger the grain size. Thus, the D-band peak having a smaller intensity than the G-band peak in FIG. 7 when compared to FIG. 6 indicates that the grain sizes for graphene sheets grown on DLC substrates are larger than comparable grain sizes obtained using SiO₂ substrates.

FIG. 8A is a plot illustrating carbon monoxide gas pressure as a function of time for graphene growth processes on different substrates according to an embodiment of the present invention. As illustrated in FIG. 8A, the graphene growth process is initiated when the plasma is ignited, which corresponds to a time of ˜3055 seconds as indicated by time T₁. Referring to curve 805, which corresponds to a silicon substrate, after the plasma is generated at time T₁, CO is produced as native oxides present on the surface of the silicon are removed as discussed in relation to FIG. 1B. The production of CO continues as the graphene growth proceeds. As illustrated in FIG. 8A, the CO signal peaks shortly after time T₁ (i.e., ˜3055 seconds ˜3070 seconds) and then decreases to a generally stable value during growth. The oxygen in the environment thus continues to react with carbon radicals to produced CO during growth.

Referring once again to FIG. 8A, curve 807 corresponds to graphene growth on an SiO₂ substrate, for example, a silicon substrate with an SiO₂ layer. After the plasma is generated at time T₁, CO is produced as the SiO₂ layer is removed to expose the silicon substrate as discussed in relation to FIG. 1B. Without limiting embodiments of the present invention, the inventors believe that all of the SiO₂ layer is removed, which correlates with the higher CO production levels on an SiO₂ substrate in comparison with a silicon substrate. The production of CO continues as the graphene growth proceeds.

FIG. 8B is a plot illustrating carbon dioxide gas pressure as a function of time for graphene growth processes on different substrates according to an embodiment of the present invention. As discussed in relation to CO production, the graphene growth process is initiated when the plasma is ignited, which corresponds to a time of ˜3055 seconds as indicated by time T₁. Referring to curve 815, which corresponds to a silicon substrate, after the plasma is generated at time T₁, CO₂ is produced as native oxides present on the surface of the silicon are removed as discussed in relation to FIG. 1B. The production of CO₂ continues as the graphene growth proceeds. Referring to curve 817, which corresponds to an SiO₂ substrate, after the plasma is generated at time T₁, CO₂ is produced as the SiO₂ layer is removed as discussed in relation to FIG. 1B. As illustrated in FIG. 8B, for SiO₂ substrates, the CO₂ signal experiences a peak after the plasma is ignited, which is consistent with removal of the SiO₂ layer. It should be noted that since the growth chamber utilizes a quartz tube, production of oxygen as a result of the plasma is expected during plasma operation, which impacts both the CO signals shown in FIG. 8A as well as the CO₂ signals shown in FIG. 8B. Moreover, it should be noted that the CO₂ signals have a pressure several orders of magnitude lower than the CO signals. This is consistent with the formation energy of CO₂ being higher than the formation energy of CO.

In addition to growing horizontal graphene sheets on silicon, embodiments of the present invention are useful for synthesizing vertical graphene nano-walls on a variety of substrates. As described more fully below, by controlling the ratio of CH₄ to H₂ gas flows to a value greater than 5.5, rather than graphene sheets, vertical graphene nano-walls are produced. In general, the growth conditions inside the PECVD growth chamber can be modified significantly through varying the plasma power, growth time, and methane (CH₄) to hydrogen (H₂) ratio. This flexibility led to our successful synthesis of vertical graphene nano-walls directly on silicon surface by increasing both the plasma power and the ratio of CH₄/H₂ partial pressures.

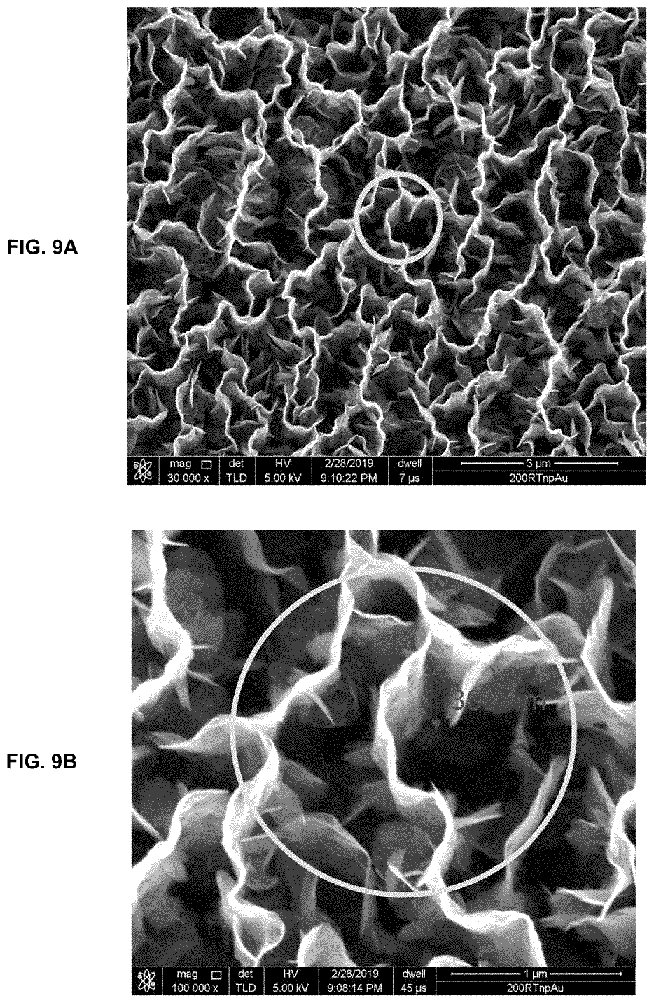

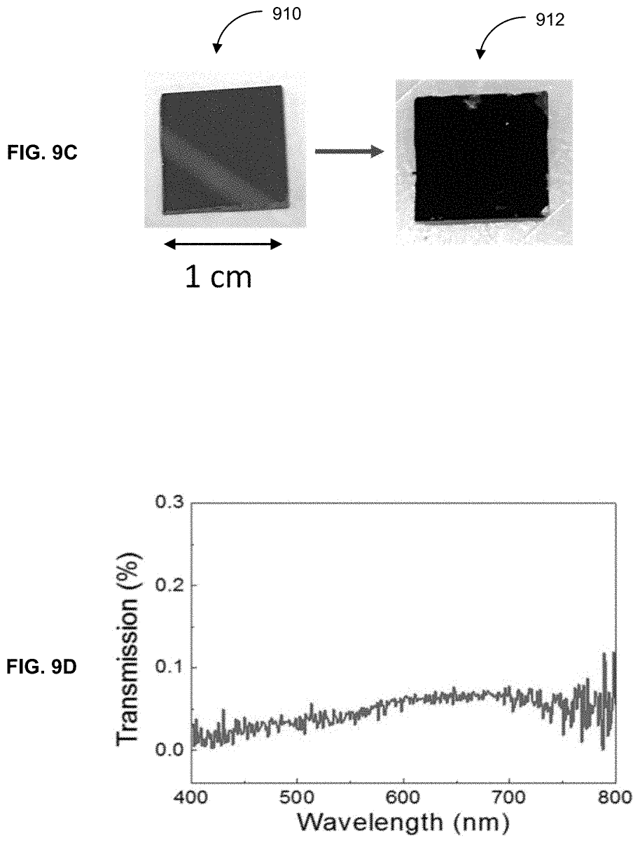

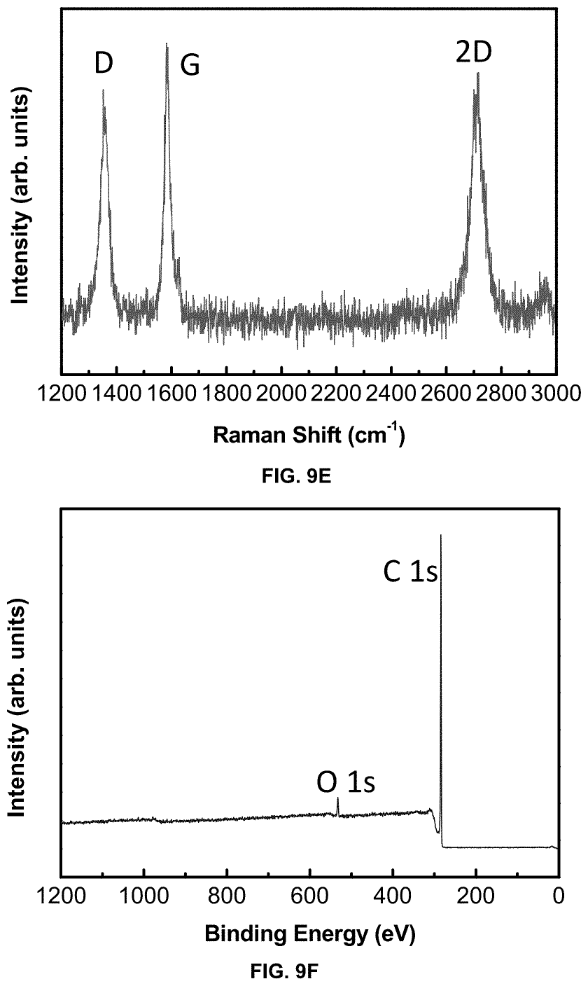

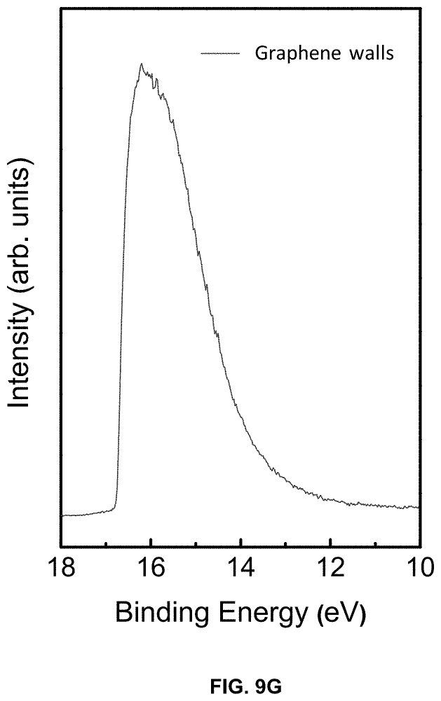

FIG. 9A is an SEM image of vertical graphene nano-walls on a silicon substrate according to an embodiment of the present invention. FIG. 9B is an enlarged image of a portion of the SEM image shown in FIG. 9A. In FIG. 9B, the portion of the SEM image enclosed by the circle in FIG. 9A was enlarged and tilted at 15°, showing a mostly consistent vertical graphene nano-wall having a height of ˜300 nm.

As will be evident to one of skill in the art, the vertical graphene nano-walls illustrated in FIG. 9A are very different from the horizontal graphene sheets shown in FIG. 2A, in part because the former led to an overall much thicker sample on the substrate. Moreover, as illustrated by the optical micrographs in FIG. 9C, the silicon substrate presented a very dark surface after the vertical graphene nano-wall growth, indicating strong optical absorption, which was in stark contrast to the metallic reflection of some horizontally grown graphene sheets.

To determine the thickness of the vertical graphene nano-walls, the tapping mode AFM was no longer suitable because the rapid height variations were too large for delicate AFM tips. Therefore, we enlarged and tilted the SEM images at 15° to estimate the thickness of the nano-walls. As shown in FIG. 9B, the average thickness of these graphene nano-walls was ˜300 nm, which was similar to the typical height of graphene nanostripes grown by PECVD on copper substrates.

As shown by the SEM image in FIGS. 9A and 9B, vertical graphene nano-walls were successfully synthesized directly on silicon by performing a PECVD growth for 10 minutes. For this PECVD growth process, a base pressure of 2.28×10⁻² Torr, a CH₄ pressure of 6.45×10⁻⁵ Torr, a N₂ pressure of 2.39×10⁻⁷ Torr, and a H₂ pressure of 8.01×10⁻⁶ Torr were utilized. These pressures were measured using RGA, which indicates that growth chamber pressures were approximately 10,000 times higher than the CH₄ partial pressure. As shown in FIGS. 9A and 9B, the graphene nano-walls fully cover the surface of the silicon substrate after 10 minutes of PECVD growth. The vertical graphene nano-walls appear to distribute uniformly over the entire (1 cm×1 cm) silicon substrate, although their surface morphology was totally different from the horizontal graphene sheets shown in FIG. 2A. The full coverage of graphene nano-walls was further confirmed by the optical micrographs shown in FIG. 9B. After 10 minutes of graphene growth, the silicon substrate revealed a totally darkened surface without any metallic reflection, indicating that graphene had fully covered the entire surface of the silicon substrate. It should be noted that the inventors have determined that graphene nano-walls and graphene sheets have distinctly different optical properties and that these differences in the optical properties of graphene nano-walls and graphene sheets may be attributed to the combined effects of larger thicknesses and different geometries of graphene nano-walls that led to substantial sub-wavelength photon scattering and trapping.

FIG. 9C illustrates optical micrographs of the silicon substrate before and after the growth of the vertical graphene nano-walls illustrated in FIG. 9A. As shown by the comparison between optical micrograph 910 (i.e., before vertical graphene nano-wall growth) and optical micrograph 912 (i.e., after vertical nano-wall growth), the vertical graphene nanowalls fully cover the silicon substrate.

Additionally, optical transmission studies were carried out by transferring graphene nano-walls from silicon onto quartz substrates and then compared with the results from horizontal graphene sheets similarly transferred from silicon to quartz substrates.

FIG. 9D is a plot of optical transmission as a function of wavelength for the vertical graphene nano-walls illustrated in FIG. 9A. The transferred graphene sheets revealed a transmission percentage more than 80% across the visible light range, indicating an average thickness less than 7 layers. In contrast, <2% optical transmission was observed from 350 nm to 800 nm for the transferred graphene nano-walls, which was consistent with the completely darkened surface of the sample fully covered by graphene nano-walls as illustrated in FIG. 9C. The vanishing optical transmission implied strong light absorption by graphene nano-walls as the result of multiple sub-wavelength scattering and effective light trapping in these quasi-one-dimensional graphene nanostructures.

As shown in FIG. 9D, the optical transmission spectra of the vertical graphene nano-walls grown on silicon demonstrates the full coverage, which produces low transmission across the visible spectrum. In order to measure the optical transmission as a function of wavelength illustrated in FIG. 9D, the vertical graphene nano-walls were grown on a silicon substrate and then transferred to quartz substrates for measurement.

Raman, XPS, and UPS studies were carried out to verify the quality of the vertical graphene nano-walls and the results were shown in FIGS. 9E-9G.

FIG. 9E is a plot illustrating the Raman spectrum for the vertical graphene nano-walls shown in FIG. 9A. As shown in FIG. 9E, the Raman spectrum taken on the vertically grown graphene nano-walls on silicon, showing sharp peaks associated with the characteristic 2D-, G- and D-bands of Raman modes of graphene. The 2D/G ratio of the Raman spectrum suggested that the vertical graphene nano-walls were consistent with graphene multilayers. Furthermore, the existence of the D-band may be attributed to the edges of vertical graphene nano-walls on the silicon substrates.

The surface characteristics of graphene nano-walls grown on silicon were also investigated using XPS/UPS, which yielded results similar to those obtained from the graphene sheets grown on silicon substrates.

FIG. 9F is a plot illustrating the XPS spectrum for the vertical graphene nano-walls shown in FIG. 9A. As illustrated in FIG. 9F, the XPS spectrum revealed a clean sample surface with only C-1s and O-1s signals. The dominant C-1s peak (>97%) was from the as-grown vertical graphene nano-walls, whereas the presence of a small O-1s peak (<3%) may be the result of broken Si—O bonds from the substrate surface. Thus, the chemical purity of the PECVD-grown vertical graphene nano-walls was confirmed since the XPS spectrum revealed only C-1s and O-1s peaks, and the O-1s peak intensity indicated that the oxygen content on the surface was less than 3% relative to carbon, suggesting that the surface composition was predominately carbon and that the oxygen content in the vertical graphene nano-walls was even less than the oxygen content in horizontally grown graphene sheets. In particular, we note that no Si peaks could be found in the XPS spectrum at binding energies between about 100 and 200 eV, which implied full coverage of graphene on the silicon substrate and further corroborates the finding from the SEM image in FIG. 2A.

FIG. 9G is a plot illustrating the UPS spectrum for the vertical graphene nano-walls shown in FIG. 9A. The UPS spectrum in FIG. 9G, revealed a work function value of 4.4 eV, which was again very close to the work function of pristine graphene. Therefore, all experimental data from Raman, XPS, and UPS studies indicated that we successfully synthesized vertical graphene nano-walls directly on silicon substrates with full coverage.

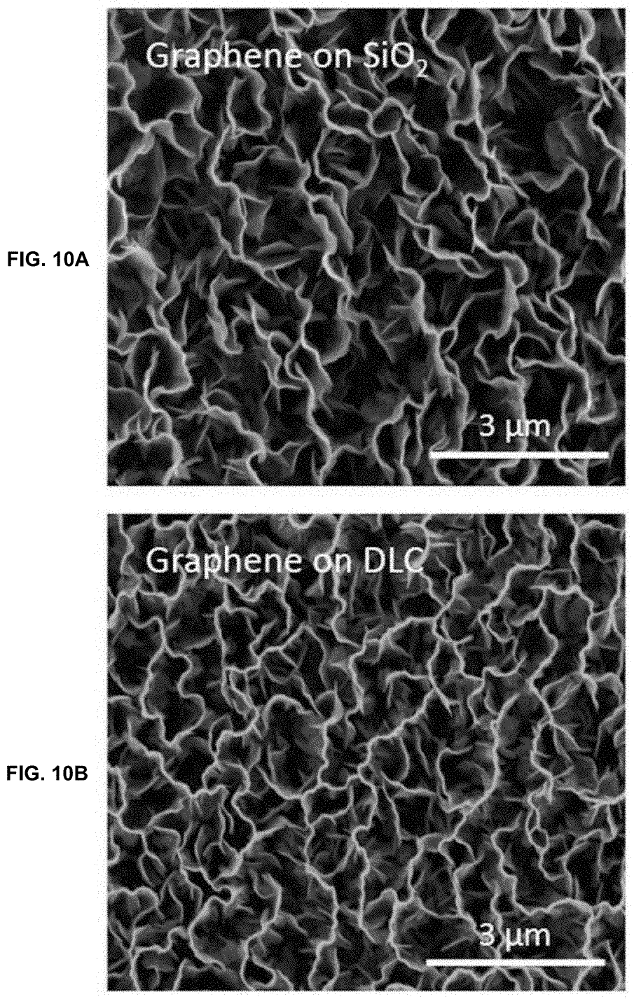

In addition to direct growth of vertical graphene nano-walls on silicon substrates, direct growth of vertical graphene nano-walls was performed on SiO₂ and DLC substrates without metal catalysis. FIG. 10A is an SEM image of vertical graphene nano-walls grown on a silicon dioxide substrate according to an embodiment of the present invention. FIG. 10B is an SEM image of vertical graphene nano-walls grown on a diamond like carbon substrate according to an embodiment of the present invention.

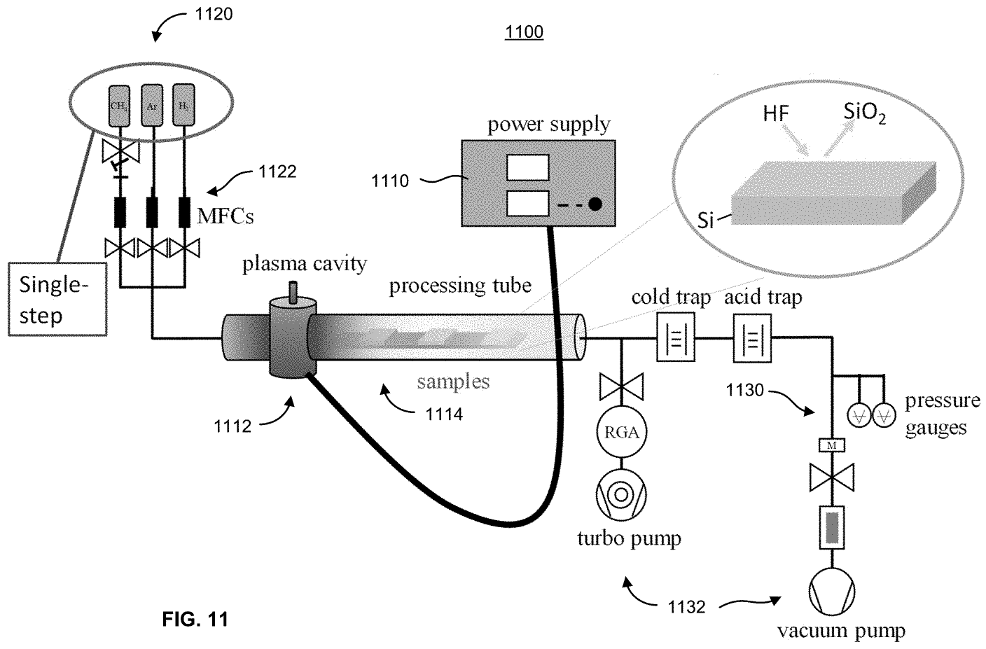

FIG. 11 is a simplified schematic diagram illustrating a PECVD graphene growth system according to an embodiment of the present invention. As shown in FIG. 11, the PECVD system 1100 includes a plasma source 1110, a plasma cavity 1112, a quartz growth tube 1114, gas cylinders 1120 (containing CH₄, Ar, and H₂), valves for mass flow control (MFC) 1122, vacuum gauges 1130, and vacuum pumps 1132. Additional description related to the PECVD system without active heating is provided in commonly assigned U.S. Pat. No. 10,041,168, the disclosure of which is hereby incorporated by reference in its entirety for all purposes.

Immediately before placing substrates (e.g., silicon, silicon dioxide, or DLC) into the processing tube, hydrofluoric acid (HF) was used to etch away the native oxides on the substrate surface (for around 20 minutes) to ensure that most of the oxides were removed. This step helped temporarily passivate the reactive silicon surface by forming silicon-hydrogen bonds on the substrate surface to minimize surface oxidation. Before turning on the plasma, we introduced all necessary gases into the tube at the same time and reached the desired partial pressures for all gases by using the MFCs to control the gas flow rates. When all gas flows reached a steady state, the plasma source was turned on to ionize gas molecules into energetic ions and radicals to induce reactions with the substrate. The surface hydrogen-silicon bond could be easily broken by the UV light and energetic particles generated in the plasma so that carbon atoms and radicals broken from the CH₄ molecules could be captured by the dangling bonds on the surface of silicon to start the nucleation of graphene structures.

In some embodiments of the present invention, the PECVD conditions were:

Chamber pressure=500 mTorr
Power=70 Watts applied at 2450 MHz (plasma volume ˜1 cm³)
CH₄ (methane) flow=1-2 sccm
H₂ (hydrogen) flow=1-2 sccm
Processing time ˜10 minutes

For this single-step PECVD growth process, the type of final graphene products is determined by three critical parameters: the ratio of methane-to-hydrogen mass flow rates, the plasma power, and the growth time. By controlling the methane and hydrogen rates, we can fabricate either horizontal graphene sheets or vertical graphene nano-walls. Specifically, when the ratio of CH₄-to-H₂ flow rates is less than 5.5, we usually obtain horizontal graphene sheets on the silicon surface. On the other hand, vertical graphene nano-walls can be synthesized by controlling the ratio of CH₄ to H₂ gas flows to a value greater than 5.5.

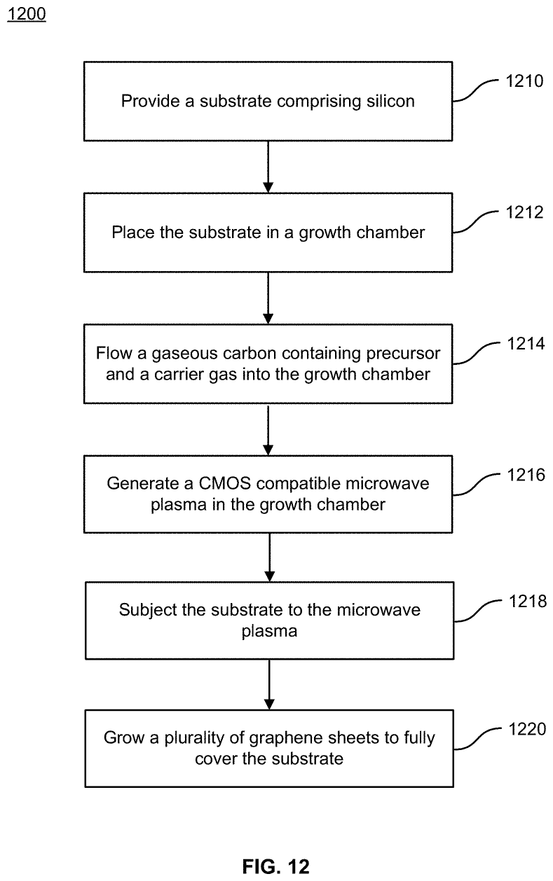

FIG. 12 is a simplified flowchart illustrating a method of growing a plurality of graphene sheets according to an embodiment of the present invention. The method 1200 includes providing a substrate comprising silicon (1210) and placing the substrate in a growth chamber (1212). In some embodiments, the substrate includes a silicon oxide layer coupled to a silicon substrate. As an example, the silicon oxide layer can be silicon dioxide. In some embodiments, the substrate has a growth area of greater than or equal to 1 cm² and less than or equal to 1590 cm², which is the area associated with a 450 mm silicon substrate.

The method also includes flowing a gaseous carbon containing precursor, for example, methane, and a carrier gas, for example, hydrogen, into the growth chamber (1214). A partial pressure ratio of the gaseous carbon containing precursor to the carrier gas is less than 5.5. In some embodiments, the mass flow rate ratio corresponds to the partial pressure ratio, providing easily measured values used to set the gas flow and pressure ratios. Flowing the gaseous carbon containing precursor can be performed by establishing a mass flow rate between 1 sccm and 2 sccm of methane in the growth chamber. Thus, in some embodiments, a methane partial pressure between 10⁻⁴ Torr and 10⁻⁶ Torr (as measured by RGA) is present in the growth chamber, more particularly, a methane partial pressure (as measured by RGA) of 10⁻⁵ Torr. In the embodiment in which a mass flow rate between 1 sccm and 2 sccm of methane is utilized, the method can also include establishing a mass flow rate between 1 sccm and 2 sccm of hydrogen in the growth chamber. Thus, a ratio of the methane flow rate to the hydrogen flow rate can be greater than 0.15 and less than 5.5, in particular, between 3.2 and 5.5.

The method further includes generating a CMOS compatible microwave plasma in the growth chamber (1216). The CMOS compatible microwave plasma can be characterized by a volume of about 1 cm³ and by a power density between 60 W/cm³ and 80 W/cm′. As discussed in relation to FIG. 2F, graphene growth occurs in a power density window that is sufficient to remove the native oxide present on the silicon surface and less than a power density that will degrade the growing graphene. In a particular embodiment, the CMOS compatible microwave plasma is a PECVD plasma and the power density is about 70 W/cm³. The substrate can be characterized by a growth temperature less than 520° C. during the process of generating the CMOS compatible microwave plasma.

Additionally, the method includes subjecting the substrate to the microwave plasma (1218) and growing the plurality of graphene sheets to fully cover the substrate (1220). As will be evident to one of skill in the art, the microwave plasma includes chemical radicals and energetic species that result from the application of the microwave radiation to the gases present in the growth chamber. Thus, as the process gases are flowed into the growth chamber in the presence of the microwave radiation, a plasma is created and the substrate is subjected to this plasma. Thus, formation of the plasma utilizes a combination of precursor gas flow and application of microwave radiation to generate the microwave plasma, which can be referred to as a PECVD plasma to which the substrate can be subjected in order to grow the graphene on silicon. Thus, the species illustrated in FIGS. 1B-1F are present in the plasma as they are created by the application of microwave radiation.

In some embodiments, the method can include forming a reduced pressure in the growth chamber prior to flowing the gaseous carbon containing precursor and the carrier gas into the growth chamber. As an example, the growth chamber pressure can be between about 100 mTorr to 1 Torr, for example, 500 mTorr, prior to growing the plurality of graphene sheets. In some embodiments, the plurality of graphene sheets are grown in a processing time less than or equal to ten minutes. The plurality of graphene sheets can be characterized by a frictional coefficient ranging between 0.0055 and 0.26, for example, between 0.015 and 0.26. The plurality of graphene sheets can be characterized by an oxygen concentration less than 5% and a silicon concentration less than 1%. Moreover, an XPS spectrum for the plurality of graphene sheets on the silicon substrate can include a carbon peak and an oxygen peak and be free of silicon peaks.

It should be appreciated that the specific steps illustrated in FIG. 12 provide a particular method of growing a plurality of graphene sheets according to an embodiment of the present invention. Other sequences of steps may also be performed according to alternative embodiments. For example, alternative embodiments of the present invention may perform the steps outlined above in a different order. Moreover, the individual steps illustrated in FIG. 12 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of growing a plurality of graphene sheets on a silicon substrate using plasma-enhanced chemical vapor deposition (PECVD), the method comprising:
placing the silicon substrate in a growth chamber, wherein the silicon substrate has a growth area of greater than or equal to 1 cm² and less than or equal to 1590 cm²;
forming a reduced pressure in the growth chamber;
flowing methane gas and hydrogen gas into the growth chamber, wherein a ratio of methane gas partial pressure to hydrogen gas partial pressure is greater than 3.2 and less than 5.5;
applying, to the growth chamber, a microwave signal having a power density between 60 Watts/cm³ and 80 Watts/cm³ to generate a microwave plasma in the growth chamber, wherein, during generation of the microwave plasma, the silicon substrate is characterized by a growth temperature less than 520° C.;
forming, in a processing time less than or equal to ten minutes, the plurality of graphene sheets on the silicon substrate, wherein the plurality of graphene sheets are characterized by a frictional coefficient ranging between 0.0055 and 0.26; and
fully covering the silicon substrate with the plurality of graphene sheets.

2. The method of claim 1 wherein the frictional coefficient is between 0.015 and 0.26.

3. The method of claim 1 wherein the plurality of graphene sheets on the silicon substrate are characterized by an oxygen concentration less than 5% and a silicon concentration less than 1%.

4. The method of claim 3 wherein an XPS spectrum for the plurality of graphene sheets on the silicon substrate includes a carbon peak and an oxygen peak and is free of silicon peaks.

5. The method of claim 1 wherein the microwave plasma has a volume of about 1 cm³ and forming the plurality of graphene sheets is performed with no active heating.

6. The method of claim 1 wherein a ratio of methane mass flow rate to hydrogen mass flow rate corresponds to the ratio of methane gas partial pressure to hydrogen gas partial pressure.

7. The method of claim 1 wherein the ratio of methane gas partial pressure to hydrogen gas partial pressure is between 1.1 and 5.5.

8. A method of growing a plurality of graphene sheets, the method comprising:
providing a substrate comprising silicon;
placing the substrate in a growth chamber;
flowing a gaseous carbon containing precursor and a carrier gas into the growth chamber, wherein a partial pressure ratio of the gaseous carbon containing precursor to the carrier gas is less than 5.5;
generating a CMOS compatible microwave plasma in the growth chamber, wherein the CMOS compatible microwave plasma is characterized by a power density between 60 W/cm³ and 80 W/cm³;
subjecting the substrate to the microwave plasma; and
growing the plurality of graphene sheets to fully cover the substrate.

9. The method of claim 8 wherein the CMOS compatible microwave plasma is a PECVD plasma and the power density is about 70 W/cm³.

10. The method of claim 9 wherein the CMOS compatible microwave plasma is characterized by a volume of about 1 cm³.

11. The method of claim 10 wherein the gaseous carbon containing precursor comprises methane and the carrier gas comprises hydrogen.

12. The method of claim 11 wherein flowing the gaseous carbon containing precursor comprises establishing a mass flow rate between 1 sccm and 2 sccm of methane in the growth chamber.

13. The method of claim 11 wherein flowing the carrier gas comprises establishing a mass flow rate between 1 sccm and 2 sccm of hydrogen in the growth chamber.

14. The method of claim 13 wherein the mass flow rate of methane and the mass flow rate of hydrogen provides a ratio of methane partial pressure to hydrogen partial pressure between 3.2 and 5.5.

15. The method of claim 13 wherein a ratio of the mass flow rate of methane to the mass flow rate of hydrogen is between 3.2 and 5.5.

16. The method of claim 8 wherein the substrate is characterized by a growth temperature less than 520° C. during generating the CMOS compatible microwave plasma.

17. The method of claim 8 wherein the substrate has a growth area of greater than or equal to 1 cm² and less than or equal to 1590 cm².

18. The method of claim 8 further comprising establishing a growth chamber pressure of about 500 mTorr prior to growing the plurality of graphene sheets.

19. The method of claim 8 wherein the plurality of graphene sheets are characterized by a frictional coefficient ranging between 0.0055 and 0.26.

20. The method of claim 19 wherein the frictional coefficient is between 0.015 and 0.26.
